(19) United States
(12) Patent Application Publication
(10) Pub. No.: US 2009/0167329 A1
(43) Pub. Date: Jul. 2, 2009

(54) METHODS AND APPARATUS FOR OPEN LAMP DETECTION IN ELECTRONIC CIRCUITS

(75) Inventors: Gilbert Seung-Zoo Lee, Gyeonggi-do (KR); James Bumsik Cho, Gyunggi-do (KR); Eung-Suen Kim, Gyunggi-do (KR); Johnny Jin-Hui Lee, Seoul (KR)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/967,876

(22) Filed: Dec. 31, 2007

(51) Int. Cl. G01R 27/08

(52) U.S. Cl. 324/705

(57) ABSTRACT

Methods and apparatus for open lamp detection in electronic circuits are disclosed. An example apparatus to perform open circuit detection associated with an electrical component included in a device disclosed herein comprises a sampling circuit to attempt to pull a sampling current through the electrical component during initialization of the device, a comparator to compare a result produced by the sampling circuit to a reference value, and a timing circuit to cause the sampling circuit to attempt to pull the sampling current through the electrical component and to cause an output of the comparator to be stored after the comparator has compared the result produced by the sampling circuit to the reference value.

### FIELD OF THE DISCLOSURE

This disclosure relates generally to electronic circuits and, more particularly, to methods and apparatus for open lamp detection in electronic circuits.

### BACKGROUND

In modern portable consumer devices, such as cellular phones and notebook computers, it is becoming increasingly popular to use white light emitting diodes (WLEDs) to implement device displays. For example, WLEDs may be used to implement a backlight of a display such that the brightness of the backlight is controlled by varying the amount of current through the WLEDs. However, as more current is allowed to flow through the WLEDs to increase the backlight's brightness, a corresponding increase in forward voltage is needed to keep the WLEDs turned on.

In many portable devices, a charge pump circuit is used to boost the forward voltage applied to the WLEDs as the battery powering the portable device discharges. For example, voltages at the cathodes of the WLEDs implementing a display's backlight may be detected and compared to a reference level to determine whether sufficient forward voltage is being applied to the WLEDs. If the detected cathode voltages are not greater than the reference level, the charge pump circuit is activated to boost the voltage applied to the anodes of the WLEDs. However, if one or more WLEDs are in an open lamp condition corresponding to, for example, a missing, disconnected or damaged WLED, the detected cathode voltage(s) for such open lamp WLED(s) may drop below the reference level even when the battery voltage is sufficient to drive the cathode voltages of the other WLEDs higher than the reference level. Such open lamp WLED(s) can, therefore, cause the charge pump to be activated prematurely, thereby reducing the battery life and/or the useful operating time for the portable device.

### BRIEF DESCRIPTION OF THE DRAWINGS

FIG. 1 is a block diagram of a first example open lamp detection circuit to detect an open lamp condition associated with a light emitting diode included in a first example device.

FIG. 2 is a block diagram of a second example open lamp detection circuit to detect open lamp conditions associated with multiple light emitting diodes included in a second example device.

FIG. 3 is a block diagram of a charge pump enable circuit implemented using the second example open lamp detection circuit of FIG. 2.

FIG. 4 is a flowchart representative of a single open lamp detection process that may be implemented by the first example open lamp detection circuit of FIG. 1

FIG. 5 is a flowchart representative of a multiple open lamp detection process that may be implemented by the second example open lamp detection circuit of FIG. 2.

FIG. 6 is a flowchart representative of a charge pump enable process that may be implemented by the example charge pump enable circuit of FIG. 3.

### DETAILED DESCRIPTION

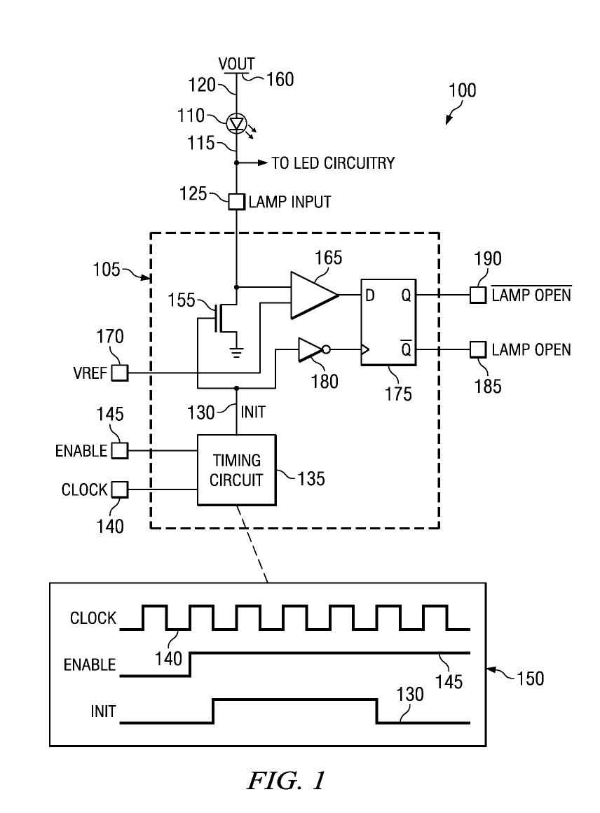

A block diagram of a first example device 100 including a first example open lamp detection circuit 105 is shown in FIG. 1. The first example open lamp detection circuit 105 is configured according to the methods and/or apparatus described herein to detect an open lamp condition associated with a light emitting diode (LED) 110 included in the first example device 100. An open lamp condition associated with the example LED 110 may correspond to, for example, the LED 110 being missing from the device or inoperative, a connection to at least one of the cathode 115 or anode 120 of the LED 110 being broken, etc. The example LED 110 may be implemented by, for example, a white LED (WLED) as discussed above.

The example open lamp detection circuit 105 includes a lamp input 125 configured to be coupled with the cathode 115 of the example LED 110. In the illustrated example, the open lamp detection circuit 105 operates during an initialization phase occurring before normal operation of the first example device 100 to determine whether the LED 110 coupled to the lamp input 125 is associated with an open lamp condition. The initialization phase is defined by an initialization signal 130 output by a timing circuit 135 included in the example open lamp detection circuit 105. The example timing circuit 135 is further configured to receive a clock signal 140 and an enable signal 145. In an example implementation, the clock signal 140 is derived from a local oscillator or other clock source included in or coupled to the first example device 100. For example, the clock signal 140 may correspond to or be derived from a system clock driving other circuitry included in the device 100. The enable signal 145 of the illustrated example may correspond to a startup signal generated when the first example device 100 is powered on, reset, etc.

An inset 150 included in FIG. 1 illustrates an example initialization signal 130 output by the example timing circuit 135 in response to an example input clock signal 140 and an example input enable signal 145. In the example illustrated in the inset 150, the enable signal 145 is asserted by a source external to the open lamp detection circuit 105 at some time after the clock signal 140 becomes active. Then, at a first predetermined time after assertion of the enable signal 145 (e.g., such as after a certain number of clock pulses have occurred), the example timing circuit 135 asserts the initialization signal 130 to indicate the start of the initialization phase. Then, at a later, second predetermined time, the example timing circuit 135 de-asserts the initialization signal 130 to indicate the end of the initialization phase. As noted above, it is during the initialization phase (i.e., when the initialization signal 130 is a logic HIGH) that the open lamp testing is performed.

To determine whether the LED 110 coupled to the lamp input 125 is associated with an open lamp condition, the example open lamp detection circuit 105 includes a sampling circuit implemented by a sampling transistor 155 to enable the operation of the LED 110 to be examined during the initialization phase defined by the initialization signal 130. The sampling transistor 155 may be implemented by a field effect transistor (FET) or any other appropriate switching device. In the illustrated example, the initialization signal 130 drives the gate input of the sampling transistor 155, causing the sampling transistor 155 to be enabled at the start of the initialization phase. Enabling the sampling transistor 155 causes the lamp input 125 and, thus, the cathode 115 of the LED 110 to be pulled toward a ground potential as shown. Because the anode 120 is coupled to the source voltage 160 (labeled as VOUT 160 in FIG. 1), a small sampling current will flow through the LED 110 when the sampling transistor 155 is enabled. This, in turn, causes a voltage differential between the source and drain of the sampling transistor 155, which further causes a positive voltage to be present at the cathode 115 and, thus, the lamp input 125, assuming that the LED 110 is operating properly. However, if the LED 110 is associated with an open lamp condition, no sampling current will flow through the LED 110. With no current able to flow through the LED 110, enabling the sampling transistor 155 during the initialization phase would cause the lamp input 125 to have a voltage of substantially zero volts corresponding to the ground potential because, with no current flow, the voltage differential between the source and drain of the sampling transistor 155 is zero.

To determine whether the voltage at the cathode 115 and, thus, the lamp input 125, corresponds to the LED 110 being in a proper operating condition or an open lamp condition, the example open lamp detection circuit 105 further includes a comparator 165. The comparator 165 may be implemented by, for example, a differential amplifier or any other comparison circuit/device. The comparator 165 of the illustrated example is configured to compare the voltage at the lamp input 125 (and, thus, the cathode 115 of the LED 110) to a reference voltage 170. The reference voltage 170 may be fixed or programmable, and is selected to be less than the expected voltage at the cathode 115 of the LED 110 (or, equivalently, the expected voltage differential between the source and drain of the sampling transistor 155) when the sampling transistor 155 is pulling the sampling current through a properly operating LED 110 (i.e., when the LED 110 is not associated with an open lamp condition). In an example implementation, the reference voltage 170 may be set to approximately 50 mV when the source voltage 160 (i.e., VOUT 160) corresponds to, for example, 3.5 V. In such an example implementation, the cathode 115 of the LED 110 (and, thus, the lamp input 125) would have a voltage greater than 50 mV when the sampling transistor 155 is enabled and the LED 110 is operating properly. However, if the LED 110 is associated with an open lamp condition, the cathode 115 of the LED 110 (and, thus, the lamp input 125) would have a voltage of approximately zero volts (corresponding to a zero voltage differential between the source and drain of the sampling transistor 155), which is less than the 50 mV reference voltage 170.

The open lamp detection circuit 105 of the illustrated example further includes a latching circuit implemented by a flip flop 175 to latch an output of the comparator 165 corresponding to the comparison of the voltage at the cathode 115 of the LED 110 (and, thus, the lamp input 125) to the reference voltage 170 during the initialization phase defined by the initialization signal 130. The flip flop 175 may be implemented by, for example, a D flip-flop (as shown), or by any other appropriate flip flop, storage element/device, etc. In the illustrate example, the data input of the flip flop 175 is coupled to the output of the comparator 165, and the clock input of flip flop 175 is coupled to the initialization signal 130 through an inverter 180. Because an inverted form of the initialization signal 130 is applied to the clock input of the flip flop 175, the data input of the flip flop 175 coupled to the output of comparator 165 will not be latched until the end of the initialization phase defined by the initialization signal 130. Waiting until the end of the initialization phase to latch (or, equivalently, to store) the output of the comparator 165 provides sufficient time for the voltage at the cathode 115 of the LED 110 (and, thus, the lamp input 125) to settle after the switching transistor 155 has been enabled.

After the output of the comparator 165 has been latched by the flip flop 175, the inverting output of the flip flop 175 provides a lamp open signal 185 and the non-inverting output of the flip flop 175 provides a lamp not open signal 190. In the illustrated example, if the LED 110 is operating properly, the voltage at the cathode 115 of the LED 110 (and, thus, the lamp input 125) will be greater than the reference voltage 170, causing a logic HIGH to be output by the comparator 165. This logic HIGH output will be latched by the flip flop 175, resulting in the lamp open signal 185 being a logic LOW and the lamp not open signal 190 being a logic HIGH. This output arrangement indicates that the LED 110 is not associated with an open lamp condition and, therefore, is operating properly. Conversely, if the LED 110 is associated with an open lamp condition, the voltage at the cathode 115 of the LED 110 (and, thus, the lamp input 125) will be less than the reference voltage 170, causing a logic LOW to be output by the comparator 165. This logic LOW output will be latched by the flip flop 175, resulting in the lamp open signal 185 being a logic HIGH and the lamp not open signal 190 being a logic LOW. This output arrangement indicates that the LED 110 is associated with an open lamp condition and, therefore, is not operating properly.

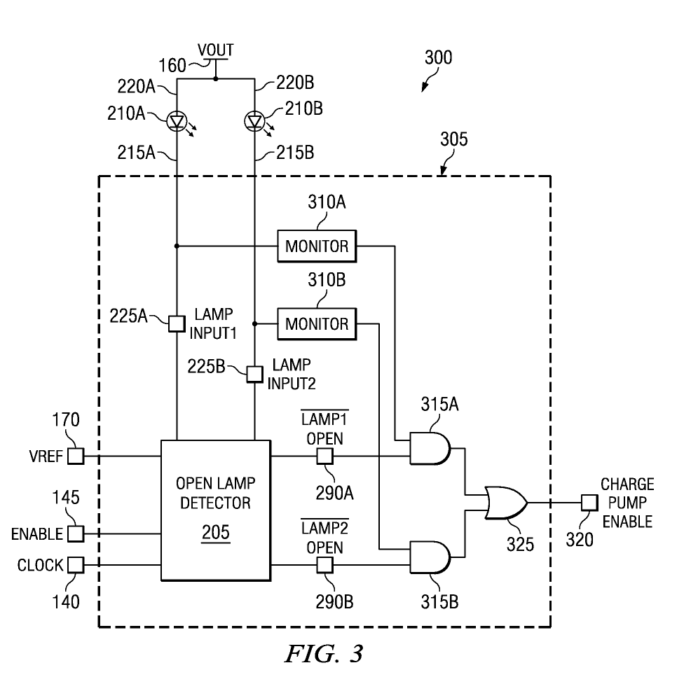

After the initialization phase defined by the initialization signal 130 is complete, the sampling transistor 155 will be disabled and, thus, will not affect the normal operation of the LED 110 and any associated LED control/monitoring circuitry coupled thereto (e.g., as indicated by the directional arrow in FIG. 1). However, the lamp open signal 185 and the lamp not open signal 190 will remain latched and, thus, may be used during later operation of the first example device 100 to indicate whether the LED 110 is associated with an open circuit condition. For example, the lamp open signal 185 may be used as an input to a charge pump enable circuit (not shown) to indicate whether a monitored voltage associated with the LED 110 should be allowed to determine whether a charge pump used to drive the source voltage 160 (i.e., VOUT 160) should be enabled. In such an example, the lamp open signal 185 being set to a logic HIGH may indicate to the charge pump enable circuit that the LED 110 corresponding to the lamp open signal 185 is associated with an open lamp condition and, thus, a monitored voltage associated with the LED 110 should not be allowed to enable the charge pump. Conversely, the lamp open signal 185 being set to a logic LOW may indicate to the charge pump enable circuit that the LED 110 corresponding to the lamp open signal 185 is not associated with an open lamp condition (e.g., is operating properly) and, thus, a monitored voltage associated with the LED 110 should be allowed to enable the charge pump. An example charge pump enable circuit employing an open lamp detection circuit (e.g., such as the open lamp detection circuit 105) is shown in FIG. 3 and discussed in greater detail below.

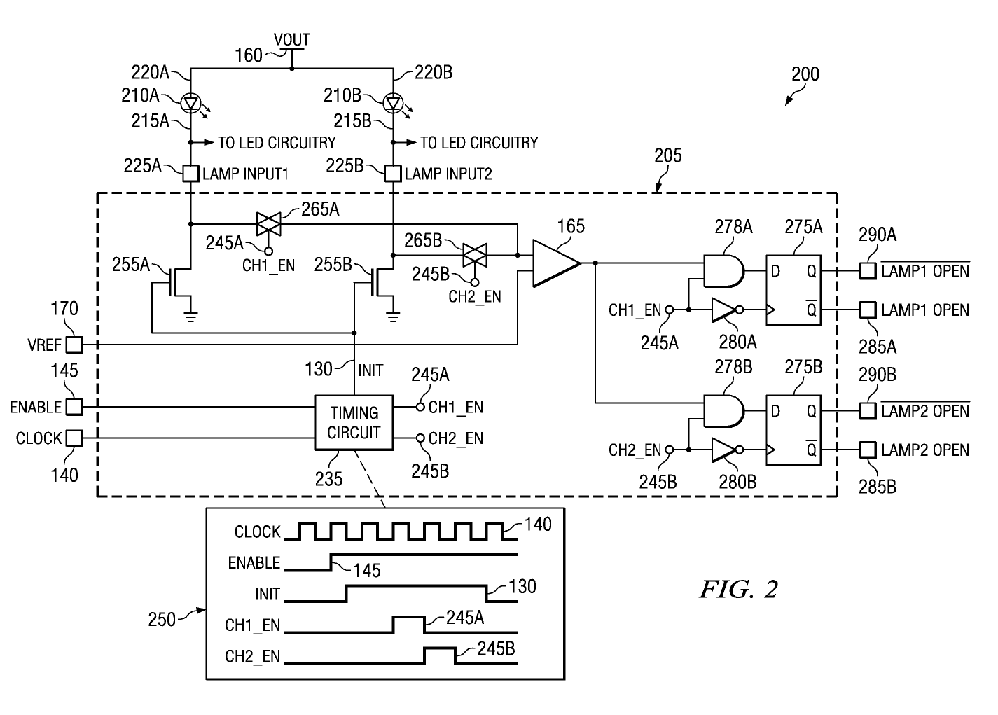

A block diagram of a second example device 200 including a second example open lamp detection circuit 205 is shown in FIG. 2. The second example open lamp detection circuit 205 is configured according to the methods and/or apparatus described herein to detect open lamp conditions associated with the LEDs 210A and 210B included in the second example device 200. The example LEDs 210A and/or 210B include respective cathodes 215A/215B, and anodes 220A/220B, and may be implemented by, for example, WLED(s) as discussed above. The second example open lamp detection circuit 205 of FIG. 2 includes some elements in common with the first example open lamp detection circuit 105 of FIG. 1. As such, like elements in FIGS. 1 and 2 are labeled with the same reference numerals. For brevity, the detailed descriptions of these like elements are provided above in connection with the discussion of FIG. 1 and, therefore, are not repeated in the discussion of FIG. 2.

Turning to FIG. 2, the second example open lamp detection circuit 205 includes a lamp input 225A configured to be coupled with the cathode 215A of the example LED 210A, and a lamp input 225B configured to be coupled with the cathode 215B of the example LED 210B. In the illustrated example, the open lamp detection circuit 205 operates during an initialization phase occurring before normal operation of the second example device 200 to determine whether either or both of the LEDs 210A and 210B coupled to the respective lamp inputs 225A and 225B are associated with open lamp condition(s). The initialization phase is defined by the initialization signal 130 output by a timing circuit 235 included in the example open lamp detection circuit 205. Similar to the example timing circuit 135 of FIG. 1, the example timing circuit 235 is configured to input the clock signal 140 and the enable signal 145 for generating the initialization signal 130 as described above in connection with FIG. 1. Additionally, the example timing circuit 235 generates a first channel enable signal 245A and a second channel enable signal 245B discussed in greater detail below.

An inset 250 included in FIG. 2 illustrates the example initialization signal 130 output by the example timing circuit 235 in response to the example input clock signal 140 and the example input enable signal 145. The initialization signal 130 and the initialization phase it defines is discussed above in connection with the inset 150 of FIG. 1. Additionally, the inset 250 also illustrates the example first and second channel enable signals 245A-245B output by the example timing circuit 235. In the example illustrated in the inset 250, at a first predetermined time after assertion of the initialization signal 130, the example timing circuit 235 asserts the first channel enable signal 245A to indicate the start of a first window of time during which the operating status of the first LED 210A may be examined. Then, at a later, second predetermined time, the example timing circuit 235 de-asserts the first channel enable signal 245A to indicate the end of this first window of time. Additionally, the example timing circuit 235 asserts the second channel enable signal 245B to indicate the start of a second window of time during which the operating status of the second LED 210B may be examined. Then, at a later, third predetermined time, the example timing circuit 235 de-asserts the second channel enable signal 245B to indicate the end of this second window of time. As discussed in greater detail below, the first and second channel enable signals 245A-245B allow the single comparator 165 to be re-used for examining the operational status of both the first and second LEDs 210A-210B in a substantially sequential manner.

To determine whether the first LED 210A coupled to the first lamp input 225A is associated with an open lamp condition, the example open lamp detection circuit 205 includes a first sampling circuit implemented by a sampling transistor 255A to enable the operation of the LED 210A to be examined during the first window of time defined by the first channel enable signal 245A. The sampling transistor 255A may be implemented by a field effect transistor (FET) or any other appropriate switching device. In the illustrated example, the initialization signal 130 drives the gate input of the sampling transistor 255A, causing the sampling transistor 255A to be enabled at the start of the initialization phase. Enabling the sampling transistor 255A causes the first lamp input 225A and, thus, the cathode 215A of the first LED 210A to be pulled toward a ground potential as shown. Because the anode 220A is coupled to the source voltage 160 (labeled as VOUT 160 in FIG. 2), a small sampling current will flow through the first LED 210A when the sampling transistor 255A is enabled. This, in turn, causes a positive voltage to be present at the cathode 215A and, thus, the first lamp input 225A (e.g., due to a voltage differential between the source and drain of the sampling transistor 255A), assuming that the first LED 210A is operating properly. However, if the first LED 210A is associated with an open lamp condition, no sampling current will flow through the LED 210A. With no current able to flow through the LED 210A, enabling the sampling transistor 255A during the initialization phase would cause the lamp input 225A to have a voltage of substantially zero volts corresponding to the ground potential (e.g., due to a substantially zero voltage differential between the source and drain of the sampling transistor 255A).

Similarly, to determine whether the second LED 210B coupled to the second lamp input 225B is associated with an open lamp condition, the example open lamp detection circuit 205 includes a second sampling circuit implemented by a sampling transistor 255B to enable the operation of the LED 210B to be examined during the second window of time defined by the second channel enable signal 245B. The sampling transistor 255B may be implemented by a field effect transistor (FET) or any other appropriate switching device. In the illustrated example, the initialization signal 130 drives the gate input of the sampling transistor 255B, causing the sampling transistor 255B to be enabled at the start of the initialization phase. Enabling the sampling transistor 255B causes the second lamp input 225B and, thus, the cathode 215B of the second LED 210B to be pulled toward a ground potential as shown. Because the anode 220B is coupled to the source voltage 160 (labeled as VOUT 160 in FIG. 2), a small sampling current will flow through the second LED 210B when the sampling transistor 255B is enabled. This, in turn, causes a positive voltage to be present at the cathode 215B and, thus, the second lamp input 225B (e.g., due to a voltage differential between the source and drain of the sampling transistor 255B), assuming that the second LED 210V is operating properly. However, if the second LED 210B is associated with an open lamp condition, no sampling current will flow through the LED 210B. With no current able to flow through the transistor 210B, enabling the sampling transistor 255B during the initialization phase would cause the lamp input 225B to have a voltage of substantially zero volts corresponding to the ground potential (e.g., due to a substantially zero voltage differential between the source and drain of the sampling transistor 255B).

To determine whether either or both of the voltages at the cathodes 215A and 215B and, thus, the respective lamp inputs 225A and 225B, correspond to either or both of the LEDs 210A and 210B being in a proper operating condition or an open lamp condition, the example open lamp detection circuit 205 further includes the single comparator 165 described above in connection with FIG. 1. The comparator 165 of the illustrated example is configured to sequentially compare the voltages at the lamp inputs 225A and 225B (and, thus, the cathode 215A of the LED 210A and the cathode 215B of the LED 210B, respectively) to a reference voltage 170. As discussed above in connection with FIG. 1, the reference voltage 170 may be fixed or programmable, and is selected to be less than the expected voltages at the cathodes 215A and 215B when the sampling currents are pulled through the properly operating LEDs 210A and 210B (i.e., when the LEDs 210A and 210B are not associated with an open lamp condition).

To enable the comparator 165 to sequentially compare the voltages at the lamp inputs 225A and 225B (and, thus, the cathode 215A of the LED 210A and the cathode 215B of the LED 210B, respectively) to the reference voltage 170, the example open lamp detection circuit 205 further includes transmission gates 265A and 265B. In the illustrated example, the first channel enable signal 245A drives a control input of the first transmission gate 265A. The first transmission gate 265A, therefore, couples the lamp input 225A (and, thus, the cathode 215A of the LED 210A) to the comparator 165 during the first window of time defined by the first channel enable signal 245A. During this first window of time, the comparator 165 is able to compare the voltage at the lamp input 225A (and, thus, the cathode 215A of the LED 210A) to the reference voltage 170. Similarly, the second channel enable signal 245B drives a control input of the second transmission gate 265B. The second transmission gate 265B, therefore, couples the lamp input 225B (and, thus, the cathode 215B of the LED 210B) to the comparator 165 during the second window of time defined by the second channel enable signal 245A. During this second window of time occurring after the first window of time, the comparator 165 is able to compare the voltage at the lamp input 225B (and, thus, the cathode 215B of the LED 210B) to the reference voltage 170

The open lamp detection circuit 205 of the illustrated example further includes a latching circuit implemented by flip flops 275A and 275B. The flip flop 275A is configured to latch an output of the comparator 165 corresponding to the comparison of the voltage at the cathode 215A of the LED 210A (and, thus, the lamp input 225A) to the reference voltage 170 during the first window of time defined by the first channel enable signal 245A. The flip flop 275B is configured to latch an output of the comparator 165 corresponding to the comparison of the voltage at the cathode 215B of the LED 210B (and, thus, the lamp input 225B) to the reference voltage 170 during the second window of time defined by the second channel enable signal 245B. The flip flops 275A and/or 275B may be implemented by, for example, a D flip-flop (as shown), or by any other appropriate flip flop, storage element/device, etc.

In the illustrated example, the data input of the flip flop 275A is coupled to the output of the comparator 165 through an AND gate 278A whose other input is driven by the first channel enable signal 245A. The clock input of example flip flop 275A is also coupled to the first channel enable signal 245A, but through an inverter 280A. The AND gate 278A and the inverter 280A cause the flip flop 275A to latch the output of the comparator 165 at the end of the first window of time defined by the first channel enable signal 245A. This arrangement provides sufficient time for the voltage at the cathode 215A of the LED 210A (and, thus, the lamp input 225A) to settle after the switching transistor 255A has been enabled, thereby allowing for an accurate comparison with the reference voltage 170.

Similarly, in the illustrated example, the data input of the flip flop 275B is coupled to the output of the comparator 165 through an AND gate 278B whose other input is driven by the second channel enable signal 245B. The clock input of example flip flop 275B is also coupled to the second channel enable signal 245B, but through an inverter 280B. The AND gate 278B and the inverter 280B cause the flip flop 275B to latch the output of the comparator 165 at the end of the second window of time defined by the second channel enable signal 245B. This arrangement provides sufficient time for the voltage at the cathode 215B of the LED 210B (and, thus, the lamp input 225B) to settle after the switching transistor 255B has been enabled, thereby allowing for an accurate comparison with the reference voltage 170.

After the output of the comparator 165 has been latched by the flip flop 275A, the inverting output of the flip flop 275A provides a lamp open signal 285A and the non-inverting output of the flip flop 275A provides a lamp not open signal 290A. In the illustrated example, if the LED 210A is operating properly, the voltage at the cathode 215A of the LED 210A (and, thus, the lamp input 225A) will be greater than the reference voltage 170, causing a logic HIGH to be output by the comparator 165 during the first window of time defined by the first channel enable signal 245A. This logic HIGH output will be latched by the flip flop 275A, resulting in the lamp open signal 285A being a logic LOW and the lamp not open signal 290A being a logic HIGH. This output arrangement indicates that the LED 210A is not associated with an open lamp condition and, therefore, is operating properly. Conversely, if the LED 210A is associated with an open lamp condition, the voltage at the cathode 215A of the LED 210A (and, thus, the lamp input 225A) will be less than the reference voltage 170, causing a logic LOW to be output by the comparator 165 during the first window of time defined by the first channel enable signal 245A. This logic LOW output will be latched by the flip flop 275A, resulting in the lamp open signal 285A being a logic HIGH and the lamp not open signal 290A being a logic LOW. This output arrangement indicates that the LED 210A is associated with an open lamp condition and, therefore, is not operating properly.

Similarly, after the output of the comparator 165 has been latched by the flip flop 275B, the inverting output of the flip flop 275B provides a lamp open signal 285B and the non-inverting output of the flip flop 275B provides a lamp not open signal 290B. In the illustrated example, if the LED 210B is operating properly, the voltage at the cathode 215B of the LED 210B (and, thus, the lamp input 225B) will be greater than the reference voltage 170, causing a logic HIGH to be output by the comparator 165 during the second window of time defined by the second channel enable signal 245B. This logic HIGH output will be latched by the flip flop 275B, resulting in the lamp open signal 285B being a logic LOW and the lamp not open signal 290B being a logic HIGH. This output arrangement indicates that the LED 210B is not associated with an open lamp condition and, therefore, is operating properly. Conversely, if the LED 210B is associated with an open lamp condition, the voltage at the cathode 215B of the LED 210B (and, thus, the lamp input 225B) will be less than the reference voltage 170, causing a logic LOW to be output by the comparator 165 during the second window of time defined by the second channel enable signal 245B. This logic LOW output will be latched by the flip flop 275B, resulting in the lamp open signal 285B being a logic HIGH and the lamp not open signal 290B being a logic LOW. This output arrangement indicates that the LED 210B is associated with an open lamp condition and, therefore, is not operating properly.

After the initialization phase defined by the initialization signal 130 is complete, the sampling transistors 255A and 255B will be disabled and, thus, will not affect the normal operation of the LEDs 210A and 210B and any associated LED control/monitoring circuitry coupled thereto (e.g., as indicated by the directional arrows in FIG. 2). However, the lamp open signals 285A-285B and the lamp not open signals 290A-290B will remain latched and, thus, may be used during later operation of the second example device 200 to indicate whether either or both of the LEDs 210A and 210B are associated with an open circuit condition. An example application employing the latched lamp not open signals 290A-290B to indicate whether either or both of the LEDs 210A and 210B are associated with an open circuit condition is shown in FIG. 3 and discussed in greater detail below.

In the illustrated example of FIG. 2, the open lamp detection circuit 205 is configured to detect open lamp conditions associated with the two LEDs 210A and 210B included in the second example device 200. However, the example open lamp detection circuit 205, and/or any other open lamp detection circuit implemented according to the methods and/or apparatus described herein, could be readily adapted to detect open lamp conditions associated with any number of LEDs included in any type of device. Furthermore, the example open lamp detection circuit 205, the example open lamp detection circuit 105 of FIG. 1, and/or any other open lamp detection circuit implemented according to the methods and/or apparatus described herein, could be readily adapted to detect open circuit condition(s) associated with any number and/or type(s) of device component(s), including but not limited to the example LEDs described above.

For example, using the second example device 200 as a reference, one (or both) of the LEDs 210A and 210B could be replaced with any type of electrical component having, for example, two connection nodes. In such an example, one of the component nodes could be coupled to the source voltage 160 and the other of the component nodes could be coupled to a detection input of the example open lamp detection circuit 205 (e.g., such as the lamp input 225A or the lamp input 225B). In such an example configuration, the open lamp detection circuit 205 could detect an open circuit condition associated with the electrical component by comparing the voltage at the detection input of the open lamp detection circuit 205 to the reference voltage 170 in the manner described above. The voltage at the detection input of the open lamp detection circuit 205 will correspond to the voltage at the electrical component node which is coupled to the detection input of the open lamp detection circuit 205. More generally, in this example, the voltage at the detection input of the open lamp detection circuit 205 would be related to the voltage drop between the two connection nodes of the electrical component. The example open lamp detection circuit 205 could be configured to detect an open circuit based on this differential voltage between electrical component nodes (as measured via the detection input of the open lamp detection circuit 205) through comparison with an appropriately set reference voltage 170.

In the examples of FIGS. 1 and 2, open lamp detection is illustrated as being based on detecting a voltage at a cathode (e.g., such as the cathodes 115, 215A and/or 215B) of a monitored LED (e.g., such as the LEDs 110, 210A and/or 210B, respectively). However, in other example implementations, open lamp detection according to the methods and apparatus described herein may be based on any appropriate voltage associated with monitored LED. For example, in one implementation, a voltage corresponding to the cathode of the monitored LED but detected via, for example, a resistive element coupled to the cathode could be used for open lamp detection. In another example implementation, a voltage at the anode of the monitored LED or a voltage corresponding to the anode but detected via, for example, a resistive element coupled to the anode could be used for open lamp detection. In yet another example implementation, a voltage detected at another location in the device but still associated with the monitored LED could be used for open lamp detection.

A block diagram of a third example device 300 including the second example open lamp detection circuit 205 of FIG. 2 to implement an example charge pump enable circuit 305 is shown in FIG. 3. The third example device 300 of FIG. 3 includes many elements in common with the second example device 200 of FIG. 2. As such, like elements in FIGS. 2 and 3 are labeled with the same reference numerals. For brevity, the detailed descriptions of these like elements are provided above in connection with the discussions of FIGS. 1 and 2 and, therefore, are not repeated in the discussion of FIG. 3.

Turning to FIG. 3, the example device 300 includes the LEDs 210A and 210B described above in connection with FIG. 2. The example device 300 also includes the example charge pump enable circuit 305 to determine whether to enable a charge pump, inductive voltage converter and/or any other voltage boosting circuit/device (not shown) to boost the source voltage 160 (i.e., VOUT 160) driving the LEDs 210A and 210B. Furthermore, the charge pump enable circuit 305 of the illustrated example includes the example open lamp detection circuit 205 to prevent the charge pump from being enabled in response to either or both of the LEDs 210A and 210B being in an open lamp condition, as discussed in greater detail below.

In the particular example of FIG. 3, and as in the example of FIG. 2, the cathode 215A of the LED 210A and the cathode 215B of the LED 210B are coupled to the respective lamp inputs 225A and 225B of the example open lamp detection circuit 205. Additionally, the cathode 215A of the LED 210A is coupled to a voltage monitor 3 10A and the cathode 215B of the LED 210B is coupled to a voltage monitor 310B. The voltage monitor 310A is configured to measure the voltage at the cathode 215A of the LED 210A and to assert an output signal when the measured voltage falls below a level indicating that the charge pump should be enabled. Similarly, the voltage monitor 310B is configured to measure the voltage at the cathode 215B of the LED 210B and to assert an output signal when the measured voltage falls below a level indicating that the charge pump should be enabled. Either or both of the voltage monitors 310A and 310B could be implemented by, for example, a comparator configured to compare an input voltage (e.g., the voltage at the cathode 215A and/or the cathode 215B) to a predetermined and/or programmable level at which the charge pump should be enabled to boost the source voltage 160 (i.e., VOUT 160).

However, the voltage at the cathode 215A and/or the voltage at the cathode 215B could also drop below this charge pump enable level if their respective LEDs 210A and 210B are associated with an open lamp condition. To prevent an open lamp condition associated with the LED 210A from enabling the charge pump, the output of the voltage monitor 310A is gated by an AND gate 315A whose other input is coupled to the lamp not open signal 290A of the example open lamp detection circuit 205. Thus, the output of the AND gate 315A will be asserted only both the voltage at the cathode 215A is below the charge pump enable threshold and the LED 210A is not in an open lamp condition. Similarly, to prevent an open lamp condition associated with the LED 210B from enabling the charge pump, the output of the voltage monitor 310B is gated by an AND gate 315B whose other input is coupled to the lamp not open signal 290B of the example open lamp detection circuit 205. Thus, the output of the AND gate 315B will be asserted only when both the voltage at the cathode 215B is below the charge pump enable threshold and the LED 210B is not in an open lamp condition.

To generate a charge pump enable signal 320, the example charge pump enable circuit 305 further includes an OR gate 325 to combine the outputs of the AND gates 315A and 315B. Such an arrangement allows a drop in voltage at either or both of the cathode 215A of the LED 210A and the cathode 215B of the LED 210B to cause the charge pump enable signal 320 to be asserted. However, the charge pump enable signal 320 will not be asserted if such a detected drop in voltage is due solely to either or both of the LEDs 210A and 210B being associated with an open lamp condition.

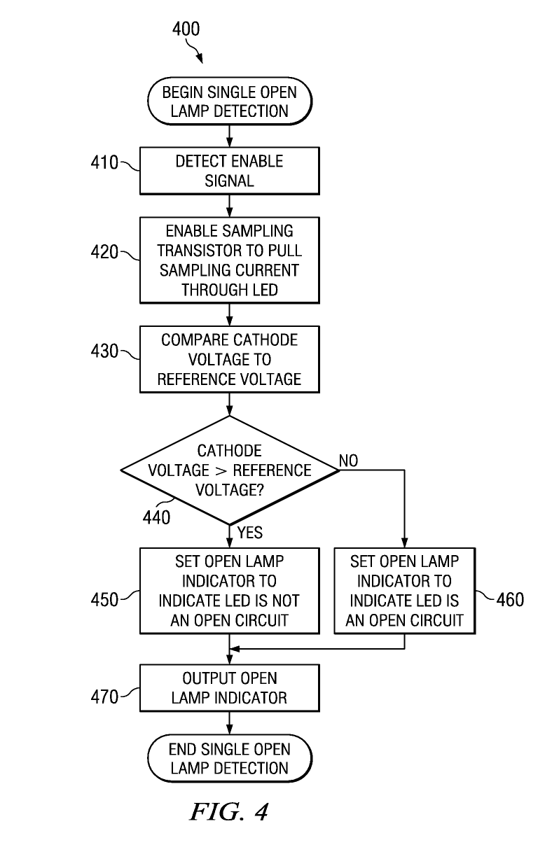

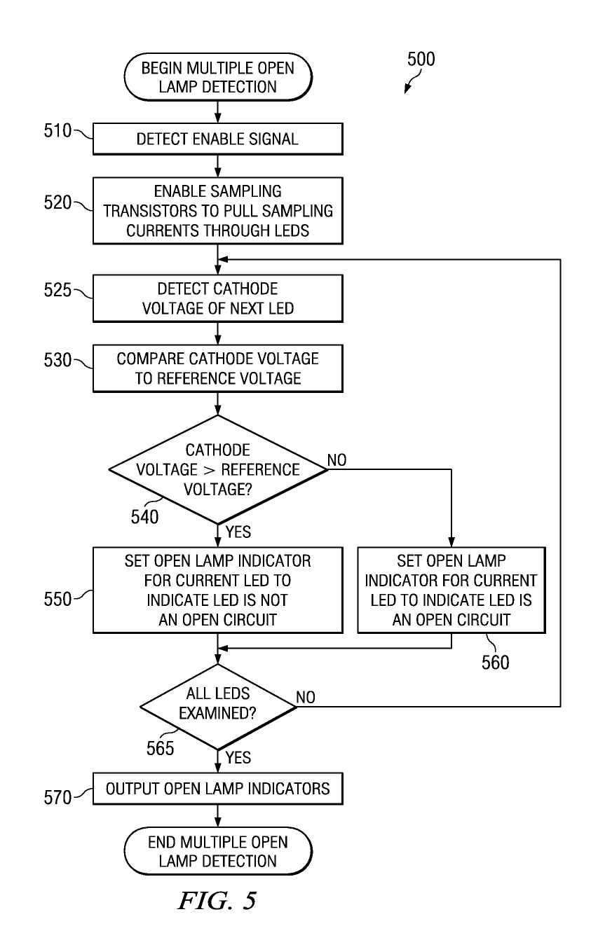

Flowcharts representative of example processes that may be implemented by all, or at least portions of, the first example device 100, the first example open lamp detection circuit 105, the second example device 200, the second example open lamp detection circuit 205, the third example device 300 and/or the example charge pump enable circuit 305 are shown in FIGS. 4-6. Additionally or alternatively, any, all or portions thereof of the first example device 100, the first example open lamp detection circuit 105, the second example device 200, the second example open lamp detection circuit 205, the third example device 300 and/or the example charge pump enable circuit 305, and/or the example processes represented by the flowcharts of FIGS. 4-5 and/or 6 could be implemented by any combination of software, firmware, hardware devices and/or combinational logic, other circuitry, etc., such as the hardware circuitry and transistors, etc., shown in FIGS. 1-3. Also, some or all of the processes represented by the flowcharts of FIGS. 4-6 may be implemented manually. Further, although the example processes are described with reference to the flowcharts illustrated in FIGS. 4-6, many other techniques for implementing the example methods and apparatus described herein may alternatively be used. For example, with reference to the flowcharts illustrated in FIGS. 4-6, the order of execution of the blocks may be changed, and/or some of the blocks described may be changed, eliminated, combined and/or subdivided into multiple blocks.

An example single open lamp detection process 400 that may be performed by the first example open lamp detection circuit 105 of FIG. 1 is illustrated in FIG. 4. The example single open lamp detection process 400 may be performed, for example, automatically upon activation of the first example device 100 of FIG. 1, upon reset of the example device 100, etc. Referring also to FIG. 1, execution of the example single open lamp detection process 400 of FIG. 4 begins at block 410 at which example open lamp detection circuit 105 detects an enable signal, such as the enable signal 145. Control then proceeds to block 420 at which the example open lamp detection circuit 105 enables a sampling transistor to pull a sampling current through an LED (e.g., such as the LED 110) to test whether the LED is associated with an open lamp condition. For example, at block 420 the timing circuit 135 may assert the initialization signal 130 after detection of the enable signal 145 at block 410. The asserted initialization signal 130 then causes the transistor 155 to turn ON and begin pulling a sampling current through the LED 110 being examined by the single open lamp detection process 400.

Next, control proceeds to block 430 at which the example open lamp detection circuit 105 compares a voltage at the cathode of the LED under test (e.g., such as the LED 110) to a reference voltage to determine whether the voltage induced by the sampling current initiated at block 420 is indicative of an open lamp condition. For example, at block 430 the comparator 165 included in the example open lamp detection circuit 105 may be used to compare the voltage at the cathode 115 of the LED 110 to the reference voltage 170. Additionally, at block 430 the comparison may be performed after a sufficient time has elapsed to allow the cathode voltage of the LED under test to settle. For example, at block 430 the output of the comparator 165 may be latched by the flip flop 175 at the end of the initialization phase defined by the initialization signal 130 to provide sufficient time for the voltage at the cathode 115 of the LED 110 to settle. Control then proceeds to block 440.

At block 440, the example open lamp detection circuit 105 determines whether the cathode voltage of the LED under test is greater than the reference voltage. For example, at block 440 the comparator 165 included in the open lamp detection circuit 105 may output a logic HIGH when the voltage at the cathode 115 of the LED 110 is greater than the reference voltage 170 and a logic LOW when the voltage at the cathode 115 of the LED 110 is less than the reference voltage 170. If the cathode voltage of the LED under test is greater than the reference voltage (block 440), control proceeds to block 450 at which the example open lamp detection circuit 105 sets an open lamp indicator to indicate that the LED is not associated with an open circuit condition or, equivalently, an open lamp condition. However, if the cathode voltage of the LED under test is not greater than the reference voltage (block 440), control proceeds to block 460 at which the example open lamp detection circuit 105 sets an open lamp indicator to indicate that the LED is associated with an open circuit condition or, equivalently, an open lamp condition.

For example, at block 450 the logic HIGH output by the comparator 165 in response to the voltage at the cathode 115 of the LED 110 being greater than the reference voltage 170 may be latched by the flip flop 175. The logic HIGH latched by the flip flop 175 results in the lamp open signal 185 being a logic LOW and the lamp not open signal 190 being a logic HIGH, thus indicating that the LED 110 is not associated with an open lamp condition. Conversely, at block 460 the logic LOW output by the comparator 165 in response to the voltage at the cathode 115 of the LED 110 being not greater than the reference voltage 170 may be latched by the flip flop 175. The logic LOW latched by the flip flop 175 results in the lamp open signal 185 being a logic HIGH and the lamp not open signal 190 being a logic LOW, thus indicating that the LED 110 is associated with an open lamp condition.

After the open lamp indicator is set at either block 450 or block 460, control proceeds to block 470. At block 470, the example open lamp detection circuit 105 outputs the open lamp indicator as set at either block 450 or block 460. For example, at block 470 the example open lamp detection circuit 105 may output the latched lamp open signal 185 and lamp not open signal 190. These latched output signals may be used during later operation of the example device 100 to indicate whether the LED 110 is associated with an open circuit condition. The example process 400 then ends.

An example multiple open lamp detection process 500 that may be performed by the second example open lamp detection circuit 205 of FIG. 2 is illustrated in FIG. 5. The multiple open lamp detection process 500 may be performed, for example, automatically upon activation of the second example device 200 of FIG. 2, upon reset of the example device 200, etc. Referring also to FIG. 2, execution of the example multiple open lamp detection process 500 of FIG. 5 begins at block 510 at which example open lamp detection circuit 205 detects an enable signal, such as the enable signal 145. Control then proceeds to block 520 at which the example open lamp detection circuit 205 enables sampling transistors to pull sampling currents through multiple LEDs (e.g., such as the LEDs 210A-210B) to test whether any or all of the LEDs are associated with open lamp conditions. For example, at block 520 the timing circuit 235 may assert the initialization signal 130 after detection of the enable signal 145 at block 510. The asserted initialization signal 130 then causes the transistors 255A-255B to turn ON and begin pulling sampling currents through the respective LEDs 210A-210B being examined by the multiple open lamp detection process 500.

Control next proceeds to block 525 at which the example open lamp detection circuit 205 samples the cathode voltage of the next one of the multiple LEDs to allow the sampled voltage to be tested against a reference voltage to determine whether the particular LED is associated with an open lamp condition. For example, at block 525 the timing circuit 235 may generate one of the channel enable signals 245A-245B to cause the corresponding transmission gate 265A-265B to pass the voltage at the cathode 215A-215B corresponding to the particular LED 210A-210B to be examined during the current sampling window of time.

Next, control proceeds to block 530 at which the example open lamp detection circuit 205 compares the voltage at the cathode of the LED (e.g., such as one of the LEDs 210A-210B) sampled at block 525 to a reference voltage to determine whether the voltage induced by the sampling current initiated at block 520 is indicative of an open lamp condition. For example, at block 530 the comparator 165 included in the example open lamp detection circuit 205 may be used to compare the reference voltage 170 to the voltage at the cathode 215A-215B of the respective LED 210A-210B whose transmission gate 265A-265B is active during the current sampling window of time defined by currently asserted channel enable signal 245A-245B. Additionally, at block 530 the comparison may be performed after a sufficient time has elapsed to allow the cathode voltage of the LED under test to settle. For example, at block 530 the output of the comparator 165 may be latched by the appropriate flip flop 275A-275B at the end of the current sampling window of time defined by the active channel enable signal 245A-245B to provide sufficient time for the cathode voltage of the LED under test to settle. Control then proceeds to block 540.

At block 540, the example open lamp detection circuit 205 determines whether the cathode voltage of the LED under test is greater than the reference voltage. For example, at block 540 the comparator 165 included in the open lamp detection circuit 205 may output a logic HIGH when the voltage at the cathode 215A-215B of the respective LED 210A-210B being passed by the transmission gates 265A-265B during the current sampling window of time is greater than the reference voltage 170, and a logic LOW when the cathode voltage being passed by the transmission gates 265A-265B during the current sampling window of time is less than the reference voltage 170. If the cathode voltage of the LED under test is greater than the reference voltage (block 540), control proceeds to block 550 at which the example open lamp detection circuit 205 sets an open lamp indicator to indicate that the current LED under test is not associated with an open circuit condition or, equivalently, an open lamp condition. However, if the cathode voltage of the LED under test is not greater than the reference voltage (block 540), control proceeds to block 560 at which the example open lamp detection circuit 205 sets an open lamp indicator to indicate that the LED under test is associated with an open circuit condition or, equivalently, an open lamp condition.

For example, at block 550 the logic HIGH output by the comparator 165 (i.e., because the cathode voltage being passed by the transmission gates 265A-265B during the current sampling window of time is greater than the reference voltage 170) may be latched by the appropriate flip flop 275A-275B. The logic HIGH latched by the appropriate flip flop 275A-275B results in this flip-flop's respective lamp open signal 285A-285B being a logic LOW and this flip-flop's respective lamp not open signal 290A-290B being a logic HIGH, thus indicating that the corresponding LED 210A-210B under test is not associated with an open lamp condition. Conversely, at block 560 the logic LOW output by the comparator 165 (i.e., because the cathode voltage being passed by the transmission gates 265A-265B during the current sampling window of time) is not greater than the reference voltage 170 may be latched by the appropriate flip flop 275A-275B. The logic LOW latched by the appropriate flip flop 275A-275B results in this flip-flop's respective lamp open signal 285A-285B being a logic HIGH and this flip-flop's respective lamp not open signal 290A-290B being a logic LOW, thus indicating that the corresponding LED 210A-210B under test is associated with an open lamp condition.

After the open lamp indicator is set at either block 550 or block 560, control proceeds to block 565. At block 565, the example open lamp detection circuit 205 determines whether all of the multiple LEDs have been examined by the multiple open lamp detection process 500. If all of the multiple LEDs have not been examined (block 565), control returns to block 525 and blocks subsequent thereto at which the example open lamp detection circuit 205 samples the cathode voltage of the next one of the multiple LEDs to allow the sampled voltage to be tested against a reference voltage to determine whether the particular LED is associated with an open lamp condition. However, if all of the multiple LEDs have been examined (block 565), control proceeds to block 570 at which the example open lamp detection circuit 205 outputs the open lamp indicators for all of the multiple LEDs as set at either block 550 or block 560 during various iterations of the example multiple open lamp detection process 500. For example, at block 570 the example open lamp detection circuit 205 may output the latched lamp open signals 285A-285B and lamp not open signals 290A-290B. These latched output signals may be used during later operation of the example device 200 to indicate whether any or all of the LEDs 210A-210B are associated with an open circuit condition. The example process 500 then ends.

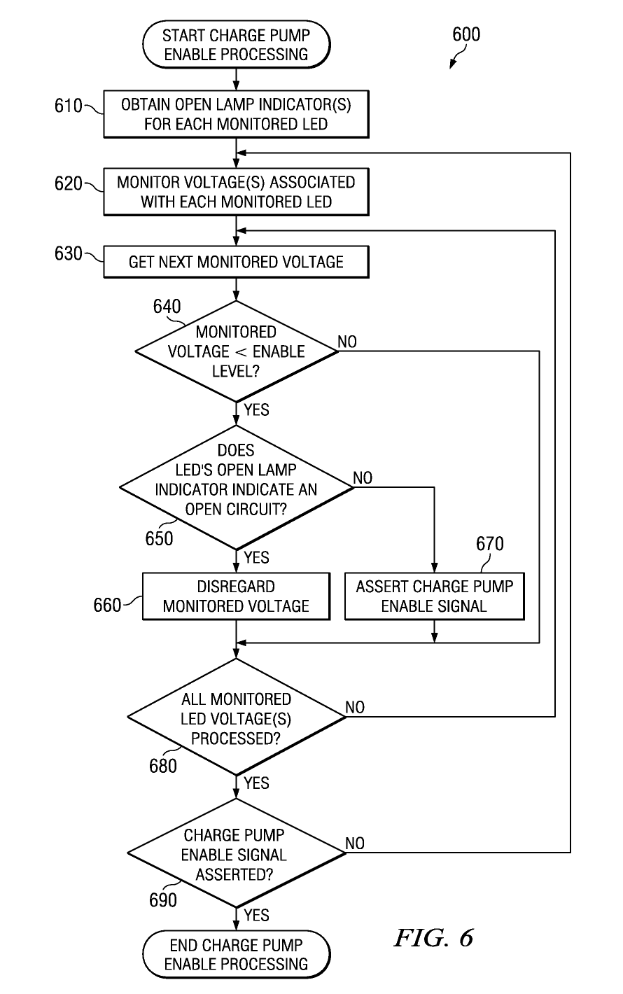

An example charge pump enable process 600 that may be performed by the example charge pump enable circuit 305 of FIG. 3 is illustrated in FIG. 6. The example charge pump enable process 600 may be performed, for example, automatically upon activation of the third example device 300 of FIG. 3, upon reset of the example device 300, upon/after completion of the initialization phase defined by, for example, the initialization signal 130, upon/after latching of, for example, the lamp open signals 285A-285B and/or the lamp not open signals 290A-290B, etc. Referring also to FIG. 3, execution of the example charge pump enable process 600 of FIG. 6 begins at block 610 at which the example charge pump enable circuit 305 obtains open lamp indicators corresponding to those LEDs being monitored to determine whether the charge pump driving the LEDs should be enabled. For example, at block 610 the example charge pump enable circuit 305 may obtain the lamp not open signals 290A-290B latched at the end of an initialization phase and corresponding, respectively, to the monitored LEDs 210A-210B.

Next, control proceeds to block 620 at which the example charge pump enable circuit 305 monitors voltages associated with the LEDs to determine whether the charge pump should be enabled to boost the forward voltage driving the LEDs. For example, at block 620 the voltage monitors 310A-310B may monitor, respectively, the voltages at the cathodes 215A-215B of the LEDs 210A-210B. Control then proceeds to block 630 at which the example charge pump enable circuit 305 gets the next monitored voltage to be tested for determining whether to enable the charge pump. Then at block 640 the example charge pump enable circuit 305 determines whether the monitored voltage obtained at block 630 is less than a charge pump enable level. As discussed above, the charge pump enable level is a predetermined and/or programmable voltage level below which the charge pump should be enabled to boost the forward voltage driving the LEDs. In an example implementation, each of the voltage monitors 310A-310B compares its respective monitored voltage to the charge pump enable level and asserts an output if the monitored voltage falls below the charge pump enable level.

Returning to block 640, if the monitored voltage is less than the charge pump enable level, control proceeds to block 650 at which the example charge pump enable circuit 305 determines whether the open lamp indicator for the LED corresponding to this monitored voltage indicates that the LED is associated with an open lamp condition or, equivalently, an open circuit condition. For example, at block 650 the example charge pump enable circuit 305 may determine whether the lamp not open signal 290A-290B for this LED is a logic HIGH indicating that the LED is not associated with an open lamp (e.g., circuit) condition, or a logic LOW indicating that the LED is associated with an open lamp (e.g., circuit) condition. If the open lamp indicator for this LED does indicate an open lamp (e.g., circuit) condition (block 650), control proceeds to block 660 at which the example charge pump enable circuit 305 disregards this LED's monitored voltage and, thus, does not assert a charge pump enable signal in response to this monitored voltage being less than the charge pump enable level. However, if the open lamp indicator for this LED does not indicate an open lamp (e.g., circuit) condition (block 650), control proceeds to block 670 at which the example charge pump enable circuit 305 asserts the charge pump enable signal in response to this monitored voltage being less than the charge pump enable level.

In an example implementation, the process at block 660 and 670 may be implemented by the AND gates 315A-315B and the OR gate 325 included in the example charge pump enable circuit 305. For example, the AND gates 315A-315B can be used to qualify the output of each voltage monitor 310A-310B using the appropriate lamp not open signal 290A-290B corresponding to the LED monitored by the voltage monitor 310A-310B. If a particular lamp not open signal 290A-290B is a logic LOW (e.g., corresponding to the open lamp condition or, equivalently, the open circuit condition), the AND gates 315A-315B will block the output of the corresponding voltage monitor 310A-310B from being applied to the OR gate 325. However, if a particular lamp not open signal 290A-290B is a logic HIGH (e.g., corresponding to a closed lamp condition or, equivalently, a closed circuit condition), the AND gates 315A-315B will pass the output of the corresponding voltage monitor 310A-310B to the OR gate 325 which, in turn, will be allowed to assert the charge pump enable signal 320.

Returning to FIG. 6, after the monitored voltage is disregarded (block 660) or allowed to assert the charge pump enable signal (block 670), or if the monitored voltage was not less than the charge pump enable level (block 640), control proceeds to block 680. At block 680, the example charge pump enable circuit 305 determines whether all monitored LED voltages have been processed. If all monitored voltages have not been processed (block 680), control returns to block 630 and blocks subsequent thereto at which the example charge pump enable circuit 305 gets the next monitored voltage to be tested for determining whether to enable the charge pump. If, however, all monitored voltages have been processed (block 680), control proceeds to block 690 at which the example charge pump enable circuit 305 determines whether the charge pump enable signal has been asserted (e.g., through at least one iteration through block 670). If the charge pump enable signal has not been asserted (block 690), control returns to block 620 and blocks subsequent thereto at which the example charge pump enable circuit 305 continues to monitors the LED voltage(s) to determine whether the charge pump should be enabled. However, if the charge pump enable signal has been asserted (block 690), the example process 600 ends.

The examples disclosed herein have typically assumed certain voltage polarities for the operational characteristics of the devices, components, circuit elements, etc., used to implement the example methods and apparatus disclosed herein. In these examples, certain positive voltages and/or voltages exceeding a threshold may cause a particular device, component, circuit element, etc., to exhibit one characteristic (e.g., such as turning ON), whereas certain non-positive (e.g., zero and/or negative) voltages and/or voltages not exceeding a threshold may cause the device, component, circuit element, etc., to exhibit a different characteristic (e.g., such as turning OFF). However, it is readily apparent that the methods and apparatus described herein can be used in example implementations based on different, or opposite, polarity definitions. As such, the example methods and apparatus described herein can be readily adapted to ensure that appropriate control/activation voltages are present to provide open lamp detection in many different electronic circuit configurations.

Finally, although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. An apparatus to perform open circuit detection associated with an electrical component included in a device, the apparatus comprising:
a sampling circuit to attempt to pull a sampling current through the electrical component during initialization of the device;
a comparator to compare a result produced by the sampling circuit to a reference value; and
a timing circuit to cause the sampling circuit to attempt to pull the sampling current through the electrical component and to cause an output of the comparator to be stored after the comparator has compared the result produced by the sampling circuit to the reference value.
